(19) United States
(12) Patent Application Publication
(10) Pub. No.: US 2024/0204791 A1
(43) Pub. Date: Jun. 20, 2024

(54) A/D CONVERTER AND SENSOR APPARATUS

(71) Applicant: ROHM CO., LTD., Kyoto (JP)

(72) Inventor: Takashi Miyake, Kyoto (JP)

(21) Appl. No.: 18/540,341

(22) Filed: Dec. 14, 2023

(30) Foreign Application Priority Data
Dec. 14, 2022 (JP) 2022-199616

(51) Int. Cl. H03M 1/34; G01L 9/00; G01R 19/00

(52) U.S. Cl. CPC H03M 1/34; G01L 9/0052; G01R 19/0038

(57) ABSTRACT

An A/D converter includes: an integrating circuit including: an amplifier including a first input end and a second input end connected to an application end of first reference voltage, a capacitor connecting the first input end and an output end of the amplifier, a first resistor connected between an application end of input voltage and the first input end, a first switch connected between the application end of the input voltage and the first input end, a second resistor connected between an application end of second reference voltage and the first input end, and a second switch connected between the application end of the second reference voltage and the first input end; a first comparator including a first input end connected to the output end and a second input end connected to the application end of the first reference voltage; and a switch controller controlling the first and second switches.

### CROSS-REFERENCE TO RELATED APPLICATION

This application is based upon and claims the benefit of priority from Japanese Patent Application No. 2022-199616, filed on Dec. 14, 2022, the entire contents of which are incorporated herein by reference.

### TECHNICAL FIELD

The present disclosure relates to an A/D converter and a sensor apparatus.

### BACKGROUND

Various sensors such as pressure sensors and temperature sensors are known in the related art For example, a pressure sensor including a resistance bridge circuit constituted by piezoresistors is known in the related art.

### BRIEF DESCRIPTION OF DRAWINGS

The accompanying drawings, which are incorporated in and constitute a part of the specification, illustrate embodiments of the present disclosure.

FIG. 1 is a diagram showing a configuration of a sensor apparatus according to a comparative example.

FIG. 2 is a timing chart showing an example of a behavior of an output voltage VINT and a comparator output CPout.

FIG. 3 is a diagram showing a configuration of an A/D converter according to a modification of the comparative example.

FIG. 4 is a timing chart for explaining problems in the comparative example.

FIG. 5 is a diagram showing a configuration example of an output stage in an amplifier.

FIG. 6 is a diagram showing a configuration of an A/D converter according to an exemplary embodiment of the present disclosure.

FIG. 7 is a flowchart according to an exemplary embodiment of the present disclosure.

FIG. 8 is a timing chart showing a first operation example according to an exemplary embodiment of the present disclosure.

FIG. 9 is a timing chart showing a second operation example according to the exemplary embodiment of the present disclosure.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Hereinafter, exemplary embodiments of the present disclosure will be described with reference to the drawings.

### 1. Comparative Example

Herein, prior to describing exemplary embodiments according to the present disclosure, a comparative example will be described for comparison. By explaining such a comparative example, problems will become clearer.

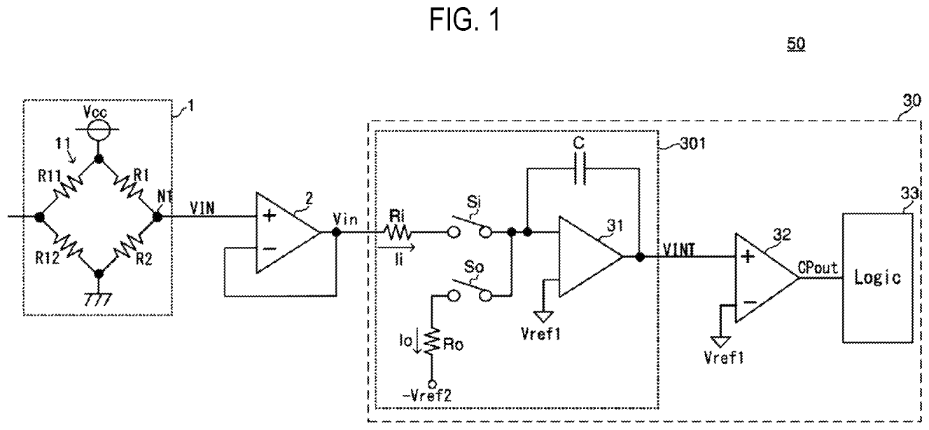

FIG. 1 is a diagram showing a configuration of a sensor apparatus 50 according to the comparative example. The sensor apparatus 50 shown in FIG. 1 includes a MEMS (Micro Electro Mechanical Systems) sensor 1, a voltage follower 2, and an A/D converter 30.

The MEMS sensor 1 includes a resistance bridge circuit 11 constituted by MEMS resistors R1, R2, R11, and R12. The MEMS resistors R1 and R2 are connected in series between an application end of a power supply voltage Vcc and an application end of a ground potential. The MEMS resistors R11 and R12 are connected in series between the application end of the power supply voltage Vcc and the application end of the ground potential.

The MEMS sensor 1 is configured by integrating a diaphragm and the resistance bridge circuit 11. For example, the resistance bridge circuit 11 is formed by using a Si substrate as the diaphragm and diffusing impurities into a surface of the Si substrate. The MEMS sensor 1 is a pressure sensor that utilizes a piezoresistance effect. The piezoresistance effect is a phenomenon in which a resistance value changes when a pressure is applied to a resistor.

When a pressure is applied to the diaphragm, resistance values change in the MEMS resistors R1, R2, R11, and R12. Depending on the resistance values of the MEMS resistors R1 and R2, an input voltage VIN is generated at a node N1 to which R1 and R2 are connected.

The use of the resistance bridge circuit is not limited to pressure sensors, but it may also be used, for example, as temperature sensors.

The voltage follower 2 is configured to output an input voltage Vin based on the input voltage VIN.

The A/D converter 30 is provided after the voltage follower 2. The A/D converter 30 is configured as a double integration type A/D converter and includes an integrating circuit 301, a comparator 32, and a logic circuit 33.

The integrating circuit 301 includes an input resistor Ri, an input switch Si, an output resistor Ro, an output switch So, a capacitor C, and an amplifier 31. An output voltage VINT of the amplifier 31 becomes an output voltage of the integrating circuit 301.

One end of the input resistor Ri is connected to an application end of the input voltage Vin. The other end of the input resistor Ri is connected to one end of the input switch Si. The other end of the input switch Si is connected to a first input end of the amplifier 31. One end of the output switch So is connected to the first input end of the amplifier 31. The other end of the output switch So is connected to one end of the output resistor Ro. The other end of the output resistor Ro is connected to an application end of a second reference voltage −Vref2. The capacitor C is connected between the first input end of the amplifier 31 and an output end of the amplifier 31. A second input end of the amplifier 31 is connected to an application end of a first reference voltage Vref1.

A first input end of the comparator 32 is connected to the output end of the amplifier 31. A second input end of the comparator 32 is connected to the application end of the first reference voltage Vref1.

Herein, an operation of the A/D converter 30 will be explained. First, by turning on the input switch Si and turning off the output switch So, an input current Ii flows through the input resistor Ri, and the capacitor C is charged. At this time, in a case where Ti is a charging period and Vint is a voltage of the capacitor C, Equation (1) is established.

$$V int = ( Ii \times Ti ) / C = V ref 1 - V {INT}_{( T = T i )} \qquad ( 1 )$$

Here, VINT_{(T=Ti)} is the output voltage of the amplifier 31 after the charging period Ti has elapsed.

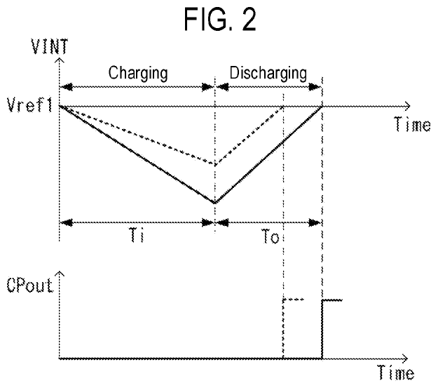

FIG. 2 is a timing chart showing an example of behaviors of the output voltage VINT and the comparator output CPout output from the comparator 32. As shown in FIG. 2, the output voltage VINT gradually decreases from the reference voltage Vref1 during the charging period Ti.

Next, by turning off the input switch Si and turning on the output switch So, an output current Io flows through the output resistor Ro, and the capacitor C is discharged. At this time, in a case where To is a discharging period required to discharge charges stored in the capacitor C during the charging period Ti, Equation (2) is established.

$$To = ( C \times V int ) / Io \qquad ( 2 )$$

Substituting Equation (1) into Equation (2),

$$To = ( C \times V int ) / Io = ( I i \times Ti ) / Io \qquad ( 3 )$$

Here, Ii=(Vin−Vref1)/Ri

Io=(Vref1+Vref2)/Ro

Here, in a case where Ri=Ro and Vref1=0 (ground potential), Equation (3) is

$$To / Ti = V in / V ref 2 \qquad ( 4 )$$

For the sake of convenience of explanation, Ri, Ro, and Vref1 are used as the above-described conditions, but the conditions are not limited thereto.

As shown in FIG. 2, the output voltage VINT gradually increases during the discharging period To, and when the discharging period To has elapsed, the output voltage VINT reaches the reference voltage Vref1. Since the comparator 32 compares the output voltage VINT with the reference voltage Vref1, the comparator output CPout is switched from a low level to a high level when the discharging period To has elapsed.

From Equation (4), in a case where the charging period Ti is a fixed value, the discharging period To changes according to the input voltage Vin. Therefore, the input voltage VIN may be measured by counting the discharging period To which is a time from a timing when the charging period Ti has elapsed to a timing when the level of the comparator output CPout is switched. The output voltage VINT indicated by a broken line in FIG. 2 indicates a case where the input voltage Vin is smaller than the output voltage VINT indicated by a solid line, and the discharging period To becomes shorter.

More specifically, the logic circuit 33 measures the fixed charging period Ti by counting clocks of a predetermined frequency by 2ⁿ. That is, the logic circuit 33 performs an n-bit counting. Then, when switching the switches Si and So to start discharging the integrating circuit 301, the logic circuit 33 resets the count to restart the count and measures the discharging period To as a count value of the clocks. From the above-described equation (4), the input voltage Vin is at the stage of a count value corresponding to To among 2ⁿ(Ti) divisions of the second reference voltage Vref2. The count value corresponding to the discharging period To becomes an output (digital output) of the A/D converter 30.

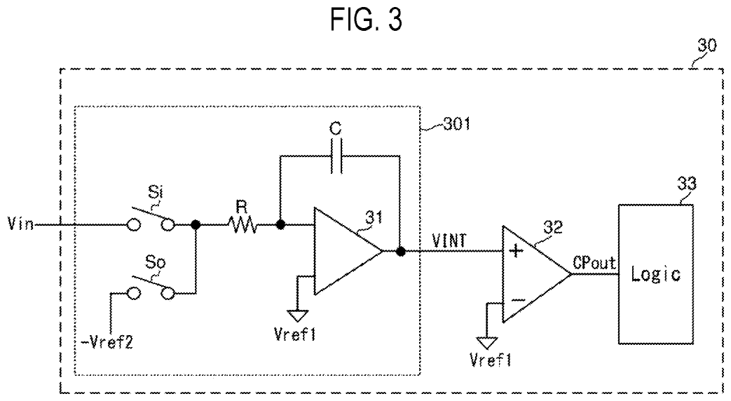

When Ri=Ro and Vref1=0 as described above, the A/D converter 30 may also be configured as shown in FIG. 3. Specifically, in the integrating circuit 301, the resistors Ri and Ro are common to a resistor R. The one end of the input switch Si is connected to the application end of the input voltage Vin. The one end of the output switch So is connected to the application end of the second reference voltage (−Vref2). The other ends of the input switch Si and the output switch So are connected in common to one end of the resistor R. The other end of the resistor R is connected to the first input end of the amplifier 31.

### 2. Problems in Comparative Example

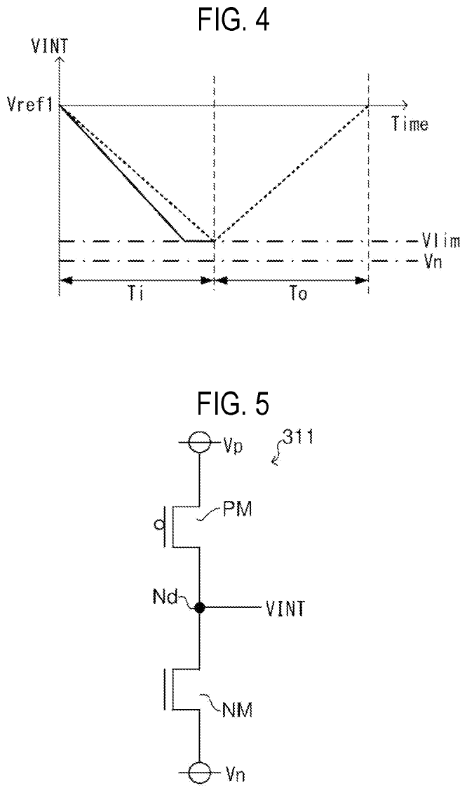

However, in the above-described comparative example, the following problems occur. From the above-described equation (4), when Vin=Vref2, Ti=To. In a timing chart of FIG. 4, a behavior of the output voltage VINT in such a case where Ti=To is indicated by a broken line. In this case, a value that the output voltage VINT reaches when the charging period Ti has elapsed is set as a lower limit value Vlim.

FIG. 5 shows a configuration of an output stage 311 in the amplifier 31. The output stage includes a PMOS transistor (P-channel MOSFET (Metal-Oxide-Semiconductor Field-Effect Transistor)) PM and an NMOS transistor (N-channel MOSFET) NM. A source of the PMOS transistor PM is connected to an application end of a positive power supply voltage Vp. A drain of the PMOS transistor PM is connected to a drain of the NMOS transistor NM at a node Nd. A source of the NMOS transistor NM is connected to an application end of a negative power supply voltage Vn. The output voltage VINT is generated at the node Nd.

The lower limit value Vlim is a lower limit value of the output voltage VINT output from the output stage 311 and is higher than the negative power supply voltage Vn by a saturation voltage generated between the drain and the source of the NMOS transistor NM (see FIG. 4).

When the input voltage Vin exceeds the second reference voltage Vref2, as indicated by a solid line in FIG. 4, the output voltage VINT may reach the lower limit value Vlim before the charging period Ti elapses such that the discharging period To does not change. That is, when Vin>Vref2, the input voltage Vin may not be measured.

Here, from the above-described equation (1), the output voltage VINT when the charging period Ti has elapsed is:

$$V INT = - ( Ii \times Ti ) / C = - ( V in \times Ti ) / ( C \times R ) \qquad ( 5 )$$

Here, R=Ri=Ro.

To widen a measurement range of the input voltage Vin, a value of R=Ri=Ro may be changed according to a maximum measured value of the input voltage Vin so that the input current Ii is constant for a fixed Ti. For example, to keep Ii=1 mA, when the maximum measured value of the input voltage Vin is 100 mV, R is set to 100Ω, and when the maximum measured value of the input voltage Vin is 1 V, R is set to 1 kΩ. Further, when Ti=To (broken line in FIG. 4), since Vin=Vref2, Vref2 may be changed according to the measured maximum value of the input voltage Vin. That is, the values of R (=Ri=Ro) and Vref2 may be varied according to the measurement range of the input voltage Vin. Therefore, the measurement range may be set before measurement.

Further, when the measurement range of the input voltage Vin is expanded according to the above-described method, a voltage value per step in resolution of the n-bit A/D output may increase, thus lowering a measurement accuracy in the measurement range before the expansion.

### 3. Embodiments of the Present Disclosure

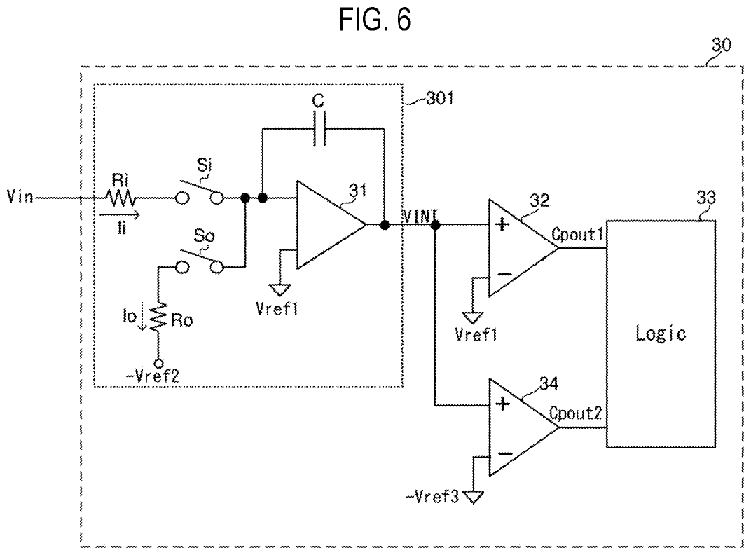

Hereinafter, embodiments of the present disclosure implemented to solve the above-described problems will be described. FIG. 6 is a diagram showing a configuration of an A/D converter 30 according to an exemplary embodiment of the present disclosure. The A/D converter 30 shown in FIG. 6 includes an integrating circuit 301, a first comparator 32, a logic circuit 33, and a second comparator 34.

In the present embodiment, the second comparator 34 is added to the configuration according to the comparative example (FIG. 1). A non-inverting input end (+) of the second comparator 34 is connected to an output end of the amplifier 31. An inverting input end (−) of the second comparator 34 is connected to an application end of a third reference voltage (−Vref3). As a result, the second comparator 34 compares the output voltage VINT and the third reference voltage (−Vref3), and outputs a comparator output Cpout2 as a comparison result. A comparator output Cpout1 of the first comparator 32 and the comparator output Cpout2 are input to the logic circuit 33. The logic circuit 33 functions as a switch controller configured to control the switches Si and So.

Herein, for the sake of convenience of explanation, it is assumed that Ri=Ro and Vref1=0 (ground potential). In this case, the integrating circuit 301 of the configuration shown in FIG. 3 described above may be applied to the configuration shown in FIG. 6. However, Ri, Ro, and Vref1 may not be the above-described conditions.

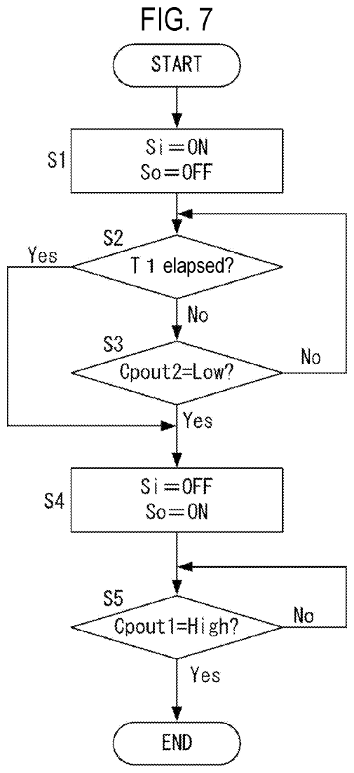

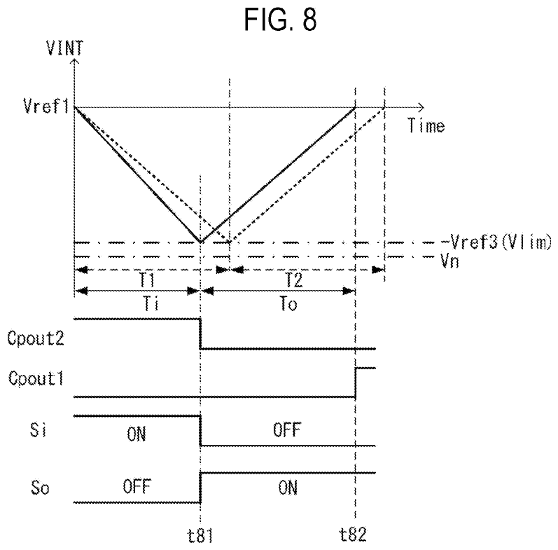

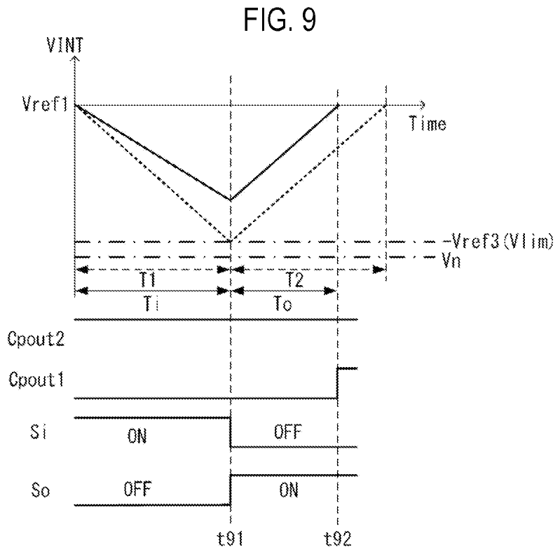

Next, an operation of the A/D converter 30 according to the present embodiment will be described with reference to a flowchart of FIG. 7 and timing charts in FIGS. 8 and 9. In FIGS. 8 and 9, the output voltage VINT, the comparator output Cpout2, the comparator output Cpout1, an on/off state of the input switch Si, and an on/off state of the output switch So are shown in this order from top.

Herein, in FIGS. 8 and 9, the output voltage VINT indicated by a broken line shows a behavior when charging and discharging are performed in the integrating circuit 301 in a case of Vin=Vref2. In this case, the charging period Ti is equal to the discharging period To according to the above-described equation (4), and in FIGS. 8 and 9, Ti at this time is set to be a predetermined period T1. Further, in FIGS. 8 and 9, the discharging period To of the output voltage VINT indicated by a broken line is set to be T2, and T1=T2.

Further, in FIGS. 8 and 9, a voltage value that the output voltage VINT shown by the broken line reaches when the predetermined period T1 has elapsed is the lower limit value Vlim, and the third reference voltage (−Vref3) is set to be Vlim.

When a process shown in FIG. 7 is started, first in step S1, the logic circuit 33 turns on the input switch Si and turns off the output switch So. As a result, charging of the capacitor C by the input current Ii is started. Immediately after the charging, the output voltage VINT becomes lower than Vref1 (=0), and Cpout1 has a low level. Further, the comparator output Cpout2 of the second comparator 34 is at a high level.

At this time, the logic circuit 33 starts counting clocks of a predetermined frequency. In this case, a count value (full count value) corresponding to the predetermined period T1 is 2ⁿ. That is, an n-bit counting is performed.

The logic circuit 33 monitors the comparator output Cpout1 of the first comparator 32 and monitors whether or not the output voltage VINT reaches the third reference voltage (−Vref3) and the comparator output Cpout2 is switched from a high level to a low level before the predetermined period T1 elapses (steps S2 and S3).

In a case where Vin>Vref2, as shown in FIG. 8, since the comparator output Cpout2 is switched from a high level to a low level before the predetermined period T1 elapses (Yes in step S3, timing t81), the process proceeds to step S4. The comparator output Cpout2 is latched and maintained at a low level thereafter. In step S4, the logic circuit 33 switches the input switch Si to the off state and the output switch So to the on state. As a result, discharging of the capacitor C is started by an output current Io. At this time, the logic circuit 33 sets the current count value to a charging period count value CNT1 corresponding to the charging period Ti. Then, the logic circuit 33 resets the count and restarts the count. That is, the counting of the discharging period To is started.

The logic circuit 33 monitors the comparator output Cpout1 (step S5). When the output voltage VINT reaches the first reference voltage Vref1 and the comparator output Cpout1 is switched from a low level to a high level (Yes in step S5, timing t82 in FIG. 8), the logic circuit 33 sets a count value at that time to a discharging period count value CNT2 corresponding to the discharging period To. Then, the logic circuit 33 calculates CNT2/CNT1 and uses the calculated value as the output of the A/D converter 30.

In this way, when Vin>Vref2, Ti<T1 and Ti (that is, CNT1) changes according to Vin. At this time, T2 (that is, CNT2) has a fixed value. Therefore, even when Vin>Vref2, Vin may be measured by CNT2/CNT1. In an ideal state with no variation factors, it is possible to set a value based only on CNT1 among CNT1 (T1) and CNT2 (T2), as the A/D output. For example, 2ⁿ/CNT1 may be used as the A/D output. However, since there are actually variation factors, by using CNT2/CNT1 as the A/D output, the variation factors are canceled to improve the accuracy.

On the other hand, when Vin<Vref2, as shown by the output voltage VINT (solid line) in FIG. 9, the output voltage VINT does not reach the lower limit value Vlim (=−Vref3) even in a case where the predetermined period T1 has elapsed. Therefore, even in the case where the predetermined period T1 has elapsed (even in a case where the full count value 2ⁿ has been counted), the comparator output Cpout2 is not switched to a low level (Yes in step S2, timing t91), and the process proceeds to step S4, where the switches Si and So are switched and the count is reset. As a result, discharging in the integrating circuit 301 is started. When the output voltage VINT reaches the first reference voltage Vref1 and the comparator output Cpout1 switches from a low level to a high level (Yes in step S5, timing t92 in FIG. 9), the logic circuit 33 sets the count value CNT2 at that time as the output of the A/D converter 30.

In this way, when Vin<Vref2, since T2 changes according to Vin with respect to T1, which is a fixed value, Vin may be measured by using the count value CNT2 as the A/D output. That is, in the present embodiment, Vin may be measured even when Vin>Vref2, such that the measurement range is expanded, and the measurement accuracy when Vin<Vref2 is not lowered.

### 4. Others

Although exemplary embodiments have been described above, the embodiments may be modified in various ways within the scope of the spirit of the present invention.

### 5. Supplementary Notes

As described above, for example, an A/D converter (30) according to an aspect of the present disclosure has a configuration that it includes:
an integrating circuit (301) including:
   an amplifier (31) including a first input end and a second input end connected to an application end of a first reference voltage (Vref1);
   a capacitor (C) connecting the first input end of the amplifier and an output end of the amplifier;
   a first resistor (Ri) connected between an application end of an input voltage (Vin) and the first input end of the amplifier;
   a first switch (Si) connected between the application end of the input voltage and the first input end of the amplifier;
   a second resistor (Ro) connected between an application end of a second reference voltage (Vref2) and the first input end of the amplifier; and
   a second switch (So) connected between the application end of the second reference voltage and the first input end of the amplifier;
a first comparator (32) including a first input end connected to the output end of the amplifier and a second input end connected to the application end of the first reference voltage; and
a switch controller (33) configured to control the first switch and the second switch,
wherein the switch controller is configured to switch the first switch to an off state and switch the second switch to an on state upon detecting that an output voltage (VINT) of the amplifier has reached a third reference voltage (−Vref3) until a predetermined period (T1) has elapsed after turning on the first switch and turning off the second switch or when the predetermined period has elapsed without the output voltage of the amplifier reaching the third reference voltage (first configuration).

Further, the A/D converter (30) of the first configuration may have a configuration that it further includes: a second comparator (34) configured to compare the output voltage (VINT) and the third reference voltage (−Vref3) and output a comparison result to the switch controller (33) (second configuration).

Further, the A/D converter (30) of the second configuration may have a configuration that the amplifier (31) includes an output stage (311) configured to output the output voltage (VINT),
wherein the output stage includes a first transistor (PM) and a second transistor (NM) connected in series between a positive power supply voltage (Vp) and a negative power supply voltage (Vn), and
wherein the third reference voltage is a voltage higher by a saturation voltage of the second transistor than the negative power supply voltage applied to the output stage included in the amplifier (third configuration).

Further, the A/D converter (30) of any one of the first to third configurations may have a configuration that it further includes: a counter (33) configured to count a charging period count value (CNT1) corresponding to a charging period until the output voltage (VINT) reaches the third reference voltage (−Vref3) after turning on the first switch (Si) and turning off the second switch (So) and count a discharging period count value (CNT2) corresponding to a discharging period until the output voltage reaches the first reference voltage (Vref1) after turning off the first switch and turning on the second switch,
wherein an output value based on the charging period count value is set as an output of the A/D converter upon detecting that the output voltage has reached the third reference voltage until the predetermined period has elapsed after turning on the first switch and turning off the second switch, and
wherein the logic circuit sets the discharging period count value as the output of the A/D converter when the predetermined period has elapsed without the output voltage reaching the third reference voltage (fourth configuration).

Further, the A/D converter (30) of the fourth configuration may have a configuration that the output value based on the charging period count value is CNT2/CNT1, where CNT1 is the charging period count value and CNT2 is the discharging period count value (fifth configuration).

Further, the A/D converter (30) of any one of the first to fifth configurations may have a configuration that the first resistor (Ri) and the second resistor (Ro) have a same resistance value, and the first reference voltage (Vref1) is a ground potential (sixth configuration).

Further, the A/D converter (30) of the sixth configuration may have a configuration that the first resistor and the second resistor are constituted as a common resistor (R) (seventh configuration).

Further, another aspect of the present disclosure provides a sensor apparatus (50) including: the A/D converter (30) of any one of the first to seventh configurations; and a resistance bridge circuit (11) provided before the A/D converter.

### INDUSTRIAL APPLICABILITY

The present disclosure can be used, for example, in various sensor apparatuses.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. An A/D converter comprising:
an integrating circuit including:
an amplifier including a first input end and a second input end connected to an application end of a first reference voltage;
a capacitor connecting the first input end of the amplifier and an output end of the amplifier;
a first resistor connected between an application end of an input voltage and the first input end of the amplifier;
a first switch connected between the application end of the input voltage and the first input end of the amplifier;
a second resistor connected between an application end of a second reference voltage and the first input end of the amplifier; and
a second switch connected between the application end of the second reference voltage and the first input end of the amplifier;
a first comparator including a first input end connected to the output end of the amplifier and a second input end connected to the application end of the first reference voltage; and
a switch controller configured to control the first switch and the second switch,
wherein the switch controller is configured to switch the first switch to an off state and switch the second switch to an on state upon detecting that an output voltage of the amplifier has reached a third reference voltage until a predetermined period has elapsed after turning on the first switch and turning off the second switch or when the predetermined period has elapsed without the output voltage of the amplifier reaching the third reference voltage.

2. The A/D converter of claim 1, further comprising: a second comparator configured to compare the output voltage and the third reference voltage and output a comparison result to the switch controller.

3. The A/D converter of claim 2, wherein the amplifier includes an output stage configured to output the output voltage,
wherein the output stage includes a first transistor and a second transistor connected in series between a positive power supply voltage and a negative power supply voltage, and
wherein the third reference voltage is a voltage higher by a saturation voltage of the second transistor than the negative power supply voltage applied to the output stage included in the amplifier.

4. The A/D converter of claim 1, further comprising: a counter configured to count a charging period count value corresponding to a charging period until the output voltage reaches the third reference voltage after turning on the first switch and turning off the second switch and count a discharging period count value corresponding to a discharging period until the output voltage reaches the first reference voltage after turning off the first switch and turning on the second switch,
wherein an output value based on the charging period count value is set as an output of the A/D converter upon detecting that the output voltage has reached the third reference voltage until the predetermined period has elapsed after turning on the first switch and turning off the second switch, and
wherein a logic circuit sets the discharging period count value as the output of the A/D converter when the predetermined period has elapsed without the output voltage reaching the third reference voltage.

5. The A/D converter of claim 4, wherein the output value based on the charging period count value is CNT2/CNT1, where CNT1 is the charging period count value and CNT2 is the discharging period count value.

6. The A/D converter of claim 1, wherein the first resistor and the second resistor have a same resistance value, and the first reference voltage is a ground potential.

7. The A/D converter of claim 6, wherein the first resistor and the second resistor are constituted as a common resistor.

8. A sensor apparatus comprising:
the A/D converter of claim 1; and
a resistance bridge circuit provided before the A/D converter.
